(19) United States
(12) Patent Application Publication
(10) Pub. No.: US 2026/0056426 A1
(43) Pub. Date: Feb. 26, 2026

(54) OPTICAL PATH CONTROL MEMBER AND DISPLAY DEVICE COMPRISING SAME

(71) Applicant: LG INNOTEK CO., LTD., Seoul (KR)

(72) Inventors: Jin Mi NOH, Seoul (KR); Byung Sook KIM, Seoul (KR); Gyu Lin LEE, Seoul (KR)

(21) Appl. No.: 19/102,701

(22) PCT Filed: Jul. 21, 2023
(86) PCT No.: PCT/KR2023/010561

§ 371 Date: Feb. 10, 2025

(30) Foreign Application Priority Data
Aug. 10, 2022 (KR) 10-2022-0099825

(51) Int. Cl. G02F 1/13; G02F 1/1335; G02F 1/167; G02F 1/1675; G02F 1/16755; G02F 1/1676; H10K 59/80

(52) U.S. Cl. CPC G02F 1/1323; G02F 1/167; G02F 1/16755; G02F 1/1676; G02F 1/133512; G02F 2001/1678; H10K 59/8792

(57) ABSTRACT

An optical path control member according to an embodiment comprises: a first substrate; a first electrode disposed on the first substrate; a second substrate disposed above the first substrate; a second electrode disposed under the second substrate; and a light conversion portion disposed between the first electrode and the second electrode, wherein the light conversion portion comprises receiving portions and partition walls which are alternately arranged, the receiving portions include disposed therein a light conversion material including a dispersion and light conversion particles dispersed in the dispersion, the light conversion particles have a sedimentation speed of 0.001-0.7 mm/day, and the sedimentation speed of the light conversion particles is the speed of the light conversion particles moving in the length direction of the receiving portions.

### TECHNICAL FIELD

The embodiment relates to an optical path control member and a display device including the same.

### BACKGROUND ART

The optical path control member is a light-shielding film that changes the path and transmittance of light. The optical path control member can be attached to the front of the display panel and used. That is, the optical path control member is attached to the display panel and adjusts the light emission angle. Accordingly, the optical path control member can be used for privacy purposes.

In addition, the optical path control member can be used on a window of a vehicle or a building. Accordingly, external light can be partially blocked to prevent glare. Or, the optical path control member can prevent the inside from being seen from the outside. That is, the optical path control member is attached to a window of a vehicle or a building and adjusts the light transmittance. Accordingly, the optical path control member can be used for privacy purposes.

The optical path control member includes an optical converter. A light conversion material is filled inside the optical converter. The light conversion material includes light conversion particles. The optical converter can operate as a light transmitting portion or a light blocking portion by dispersion and aggregation of the light conversion particles.

The optical path control member is attached to a screen or a window of a display. Therefore, when the optical path control member operates for privacy purposes, the light conversion particles can be settled in a direction of gravity. Accordingly, light can be transmitted in one area of the optical path control member.

Therefore, a new structure of the optical path control member and a driving method thereof that can solve the above-described problems are required.

### DISCLOSURE

### Technical Problem The embodiment provides an optical path control member having improved light shielding characteristics and driving speed.

### Technical Solution

An optical path control member according to an embodiment comprises: a first substrate; a first electrode disposed on the first substrate; a second substrate disposed on the first substrate; a second electrode disposed under the second substrate; and an optical converter disposed between the first electrode and the second electrode, wherein the optical converter comprises alternately disposed receiving portions and partition walls, and a light conversion material comprising a dispersion liquid and light conversion particles dispersed in the dispersion liquid is disposed inside the receiving portion, and a sedimentation velocity of the light conversion particles is 0.001 mm/day to 0.7 mm/day, and the sedimentation velocity of the light conversion particles is a velocity of the light conversion particles moving in a longitudinal direction of the receiving portion.

### Advantageous Effects

The optical path control member according to the embodiment includes light conversion particles having a sedimentation velocity of a set range. Accordingly, when the optical path control member is driven in a privacy mode or an off state, the sedimentation rate of the light conversion particles can be reduced. Accordingly, the optical path control member according to the embodiment can be driven for a long time with improved light-shielding characteristics.

In addition, the optical path control member according to the embodiment includes a receiving portion. The receiving portion includes a first region and a second region. The sedimentation velocity of the light conversion particles arranged in the first region is small. Accordingly, the light-shielding characteristics of the optical path control member can be prevented from being reduced in the privacy mode.

In addition, the moving speed of the light conversion particles arranged in the second region is large. And therefore, the driving characteristics of the optical path control member can be improved. Accordingly, the driving speed of the optical path control member can be improved.

### DESCRIPTION OF DRAWINGS

FIG. 1 is a perspective view of an optical path control member according to an embodiment.

FIG. 2 and FIG. 3 are cross-sectional views taken along the A-A′ region of FIG. 1.

FIG. 4 and FIG. 5 are drawings for explaining the sedimentation of light conversion particles of an optical path control member according to an embodiment.

FIG. 6 is a top view of an optical path control member according to an embodiment.

FIG. 7 is a cross-sectional view taken along the B-B′ region of FIG. 6.

FIG. 8 is a cross-sectional view taken along the C-C′ region of FIG. 6.

FIG. 9 is another cross-sectional view taken along the B-B′ region of FIG. 6.

FIG. 10 is another cross-sectional view taken along the C-C′ region of FIG. 6.

FIG. 11 is another cross-sectional view taken along the B-B′ region of FIG. 6.

FIG. 12 is another cross-sectional view taken along the C-C′ region of FIG. 6.

FIG. 13 is a top view of an optical path control member according to another embodiment.

FIG. 14 is a top view of an optical path control member according to another embodiment.

FIG. 15 is a drawing for comparing the sedimentation of light conversion particles according to an embodiment and a comparative example.

FIGS. 16 and 17 are cross-sectional views of a display device to which an optical path control member according to an embodiment is applied.

FIGS. 18 to 22 are drawings for explaining one embodiment of a display device to which an optical path control member according to an embodiment is applied.

### BEST MODE

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to the drawings.

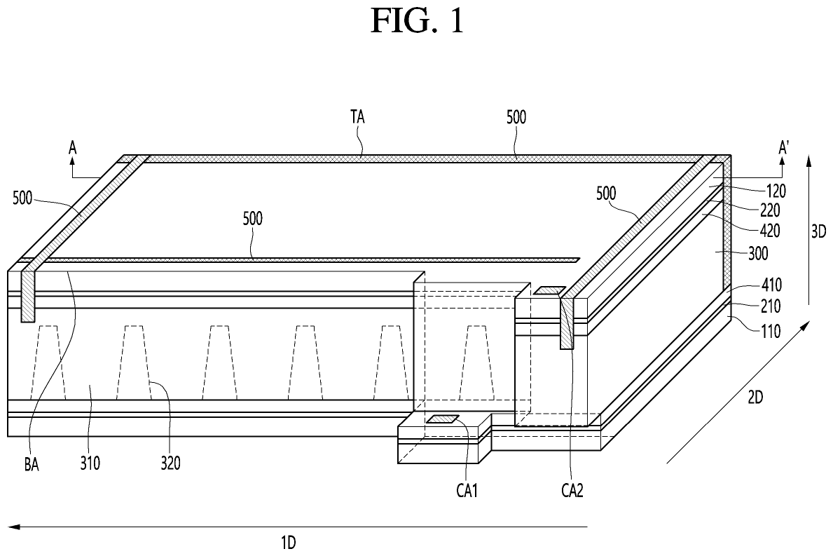

FIGS. 1 to 3 are drawings for describing an optical path control member according to an embodiment.

Referring to FIG. 1, the optical path control member 1000 includes a first substrate 110, a second substrate 120, a first electrode 210, a second electrode 220, and an optical converter 300.

The first substrate 110 supports the first electrode 210. In addition, the second substrate 120 supports the second electrode 220. The first substrate 110 and the second substrate 120 may be rigid or flexible.

In addition, at least one substrate among the first substrate 110 and the second substrate 120 may be transparent. For example, at least one substrate among the first substrate 110 and the second substrate 120 may include a transparent substrate that can transmit light.

At least one substrate among the first substrate 110 and the second substrate 120 may include glass, plastic, or a flexible polymer film. For example, the flexible polymer film may include any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS). However, the embodiment is not limited thereto.

Additionally, at least one of the first substrate 110 and the second substrate 120 may be a flexible substrate.

In addition, at least one of the first substrate 110 and the second substrate 120 may be a curved or bent substrate. Accordingly, the optical path control member may also have flexible, curved or bent characteristics. Accordingly, the optical path control member may be changed into various designs.

The first substrate 110 and the second substrate 120 extend in a first direction 1D, a second direction 2D, and a third direction 3D.

The first direction 1D may be a length direction of the first substrate 110 and the second substrate 120. The second direction 2D may be a width direction of the first substrate 110 and the second substrate 120. The third direction 3D may be a thickness direction of the first substrate 110 and the second substrate 120.

The first substrate 110 and the second substrate 120 have a thickness within a set range. For example, the first substrate 110 and the second substrate 120 may each have a thickness of 25 μm to 150 μm.

The first electrode 210 is disposed on one surface of the first substrate 110. In detail, the first electrode 210 is disposed on the upper surface of the first substrate 110. That is, the first electrode 210 is disposed between the first substrate 110 and the second substrate 120.

In addition, the second electrode 220 is disposed on one surface of the second substrate 120. In detail, the second electrode 220 is disposed on the lower surface of the second substrate 120. That is, the second electrode 220 is disposed between the first substrate 110 and the second substrate 120. In addition, the second electrode 220 faces the first electrode 210.

At least one of the first electrode 210 and the second electrode 220 includes a transparent conductive material. For example, at least one of the first electrode 210 and the second electrode 220 may include a conductive material having a light transmittance of 80% or more. For example, at least one of the first electrode 210 and the second electrode 220 may include indium tin oxide, indium zinc oxide, copper oxide, tin oxide, zinc oxide, or titanium oxide.

The first electrode 210 and the second electrode 220 may each have a thickness of 10 nm to 300 nm.

Alternatively, at least one of the first electrode 210 and the second electrode 220 may include various metals. Accordingly, the resistance of the electrode may be reduced. For example, at least one of the first electrode 210 and the second electrode 220 may include at least one metal among chromium (Cr), nickel (Ni), copper (Cu), aluminum (Al), silver (Ag), molybdenum (Mo), gold (Au), titanium (Ti), and alloys thereof.

In addition, at least one of the first electrode 210 and the second electrode 220 may be formed as a mesh-shaped electrode.

Accordingly, since the electrode is not recognized from the outside, visibility is improved. In addition, since the light transmittance is increased by the opening, the brightness of the optical path control member is improved.

The first electrode 210 and the second electrode 220 may be arranged on the entire surface of one surface of the first substrate 110 and the second substrate 120, respectively. In detail, the first electrode 210 and the second electrode 220 may be arranged as surface electrodes on one surface of the first substrate 110 and the second substrate 120, respectively.

Alternatively, the first electrode 210 and the second electrode 220 may be arranged as pattern electrodes on one surface of the first substrate 110 and the second substrate 120, respectively. That is, the first electrode 210 and the second electrode 220 may be arranged as a plurality of pattern electrodes on one surface of the first substrate 110 and the second substrate 120, respectively.

The first substrate 110 and the second substrate 120 each include a protrusion. The first substrate 110 includes a first protrusion. The second substrate 120 includes a second protrusion. The first protrusion and the second protrusion include a connection area. The connection area is connected to an external circuit board.

In detail, the first protrusion includes a first connection area CA1, and the second protrusion includes a second connection area CA2.

A conductive material is exposed on the upper surface of each of the first connection area CA1 and the second connection area CA2. For example, the first electrode 210 is exposed on the first connection area CA1. In addition, a conductive material 700 is exposed on the second connection area CA2. That is, the second protrusion includes a cutting area. The conductive material is filled inside the cutting area. By this, the second connection area CA2 can be formed.

The optical path control member is electrically connected to an external circuit board by the first connection area CA1 and the second connection area CA2.

The optical converter 300 is arranged between the first substrate 110 and the second substrate 120. In detail, the optical converter 300 is arranged between the first electrode 210 and the second electrode 220.

An adhesive layer 410 is arranged between the first electrode 210 and the optical converter 300. As a result, the first substrate 110 and the optical converter 300 can be adhered.

A buffer layer 420 is arranged between the second electrode 220 and the optical converter 300. As a result, the adhesion between the second electrode 220 and the optical converter 300 is improved.

The optical converter 300 includes a plurality of partition walls 310 and a plurality of receiving portions 320. A light conversion material 330 is arranged inside the receiving portion 320. The light conversion material 330 includes light conversion particles and dispersion liquid. The light conversion particles move according to the application of voltage. The dispersion liquid disperses the light conversion particles. The light transmission characteristics of the optical path control member change by the light conversion particles.

The second substrate 120 includes a plurality of cutting areas. A sealing material is filled in the cutting areas, and thereby forming a sealing portion 500. The light conversion material 330 is sealed by the sealing portion 500.

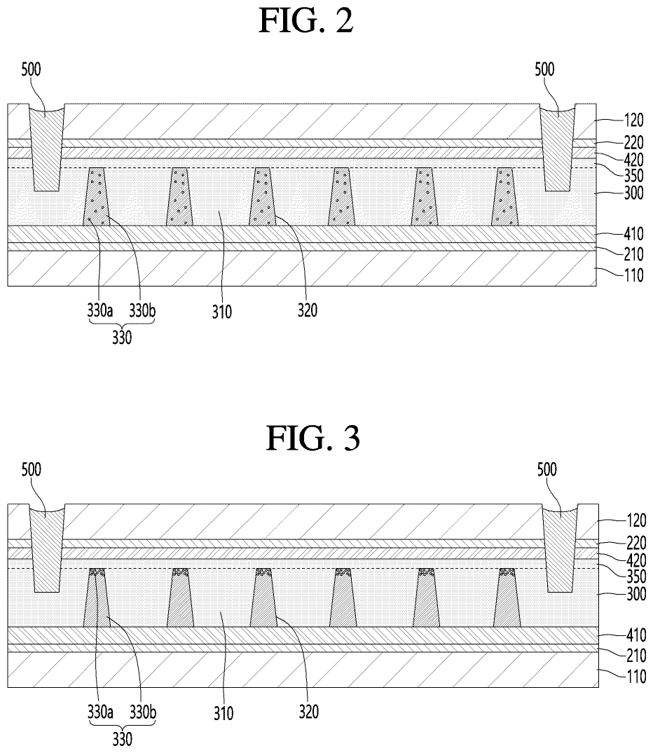

FIG. 2 and FIG. 3 are cross-sectional views taken along the A-A′ region of FIG. 1.

Referring to FIGS. 2 and 3, the optical converter 300 includes a partition wall 310 and a receiving portion 320.

The partition wall 310 is a partition wall region that partitions the receiving portion. That is, the partition wall 310 transmits light. Light emitted from the first substrate 110 or the second substrate 120 direction transmits the partition wall.

The widths of the partition wall 310 and the receiving portion 320 are different. For example, the width of the partition wall 310 is larger than the width of the receiving portion 320.

In addition, the width of the receiving portion 320 narrows as it extends from the first electrode 210 toward the second electrode 220.

The partition wall 310 and the receiving portion 320 are alternately arranged. That is, each partition wall 310 is arranged between adjacent receiving portions 320. In addition, each receiving portion 320 is arranged between adjacent partition walls 310.

The partition wall 310 includes a transparent material. The partition wall 310 includes a material that can transmit light.

The partition wall 310 may include a resin material. For example, the partition wall 310 may include a photocurable resin material. For example, the partition wall 310 may include a UV resin or a transparent photoresist. Alternatively, the partition wall 310 may include a urethane resin or an acrylic resin, etc.

The receiving portion 320 is formed by partially penetrating the optical converter 300. Accordingly, the receiving portion 320 is in contact with the adhesive layer 410, and further, the receiving portion is spaced apart from the buffer layer 420. Accordingly, a base 350 is formed between the receiving portion 320 and the buffer layer 420.

A light conversion material 330 is arranged inside the receiving portion 320. The light conversion material 330 includes light conversion particles 330a and dispersion liquid 330b.

The dispersion liquid 330b disperses the light conversion particles 330a. The dispersion liquid 330b includes a transparent substance. The dispersion liquid 330b may include a nonpolar solvent. In addition, the dispersion liquid 330b may include a substance that can transmit light. For example, the dispersion liquid 330b may include at least one substance among a halocarbon oil, a paraffin oil, and isopropyl alcohol.

The light conversion particles 330a include a substance that can absorb light. That is, the light conversion particles 330a are light absorbing particles And the light conversion particles 330a have a color. For example, the light conversion particles 330a may have a black color. For example, the light conversion particles 330a may include carbon black particles.

The light conversion particles 330a have a surface that is charged and thus have polarity. For example, the surface of the light conversion particles 330a may be negatively charged. Accordingly, the light conversion particles 330a move toward the first electrode 210 or the second electrode 220 by the application of voltage.

The light transmittance of the receiving portion 320 changes by the light conversion particles 330a. Accordingly, the receiving portion 320 changes into a light blocking portion or a light transmitting portion. That is, the transmittance of light passing through the receiving portion 330a may change by the dispersion and aggregation of the light conversion particles 330a.

For example, the optical path member can be changed from a first mode to a second mode by applying a voltage. Or, the optical path member can be changed from the second mode to the first mode by applying a voltage.

The receiving portion 320 becomes a light blocking portion in the first mode. As a result, the light emitted at a set angle is blocked. That is, the viewing angle of a user looking from the outside is narrowed. Therefore, the optical path control member operates in a privacy mode.

In addition, the receiving portion 320 becomes a light transmitting portion in the second mode. As a result, light is transmitted through both the partition wall 310 and the receiving portion 320. That is, the viewing angle of a user looking from the outside is widened. Therefore, the optical path control member operates in a public mode.

The switching from the first mode to the second mode is implemented by the movement of the light conversion particles 330a. That is, the surface of the light conversion particles 330a has a charge. The light conversion particles can move toward the second electrode to which a positive voltage is applied according to the characteristics of the charge.

For example, when no voltage is applied to the optical path control member, the light conversion particles 330a are uniformly dispersed in the dispersion liquid 330b. Accordingly, the receiving portion 320 blocks light by the light conversion particles 330a. Accordingly, the receiving portion 320 is driven as the light blocking portion in the first mode.

In addition, when voltage is applied to the optical path control member, the light conversion particles 330a move. For example, voltage may be transmitted to the receiving portion 320 through the first electrode 210 and the second electrode 220. Accordingly, the light conversion particles 330a may move toward one end or the other end of the receiving portion 320. That is, the light conversion particles 330a may move toward the second electrode 220 to which a positive voltage is applied.

For example, when voltage is applied to the first electrode 210 and/or the second electrode 220, an electric field is formed between the first electrode 210 and the second electrode 220. The light conversion particles 330a, which are negatively charged, can move toward the second electrode 220 using the dispersion liquid 330b as a medium.

For example, in an initial mode (power-off state) or a mode in which no voltage is applied, as shown in FIG. 2, the light conversion particles 330a are uniformly dispersed within the dispersion liquid 330b. Accordingly, the receiving portion 320 is driven as a light blocking portion.

In addition, in a mode in which voltage is applied, as shown in FIG. 3, the light conversion particles 330a can move toward the second electrode 220 within the dispersion liquid 330b, that is, the light conversion particles 330a move in one direction. By this, the receiving portion 320 is driven as a light transmitting portion.

Accordingly, the optical path control member is driven in two modes according to the user's surrounding environment. When the user wants light transmission only at a specific viewing angle, the receiving portion is driven as a light blocking portion. Or, when the user wants a wide viewing angle, the receiving portion is driven as a light transmitting portion.

Therefore, the optical path control member can be driven in two modes according to the user's request. Therefore, the optical path member can be driven in various environments.

Meanwhile, the optical path control member according to the embodiment is attached to the screen of the display device.

The optical path control member defines a lower area BA and an upper area TA. The lower area BA is an area corresponding to the lower part of the screen of the display device. The upper area TA is an area corresponding to the upper part of the screen of the display device.

For example, the optical path control member defines an area where the connection areas CA1, CA2 are arranged as a lower area BA. Additionally, the opposite area is defined as the upper area TA.

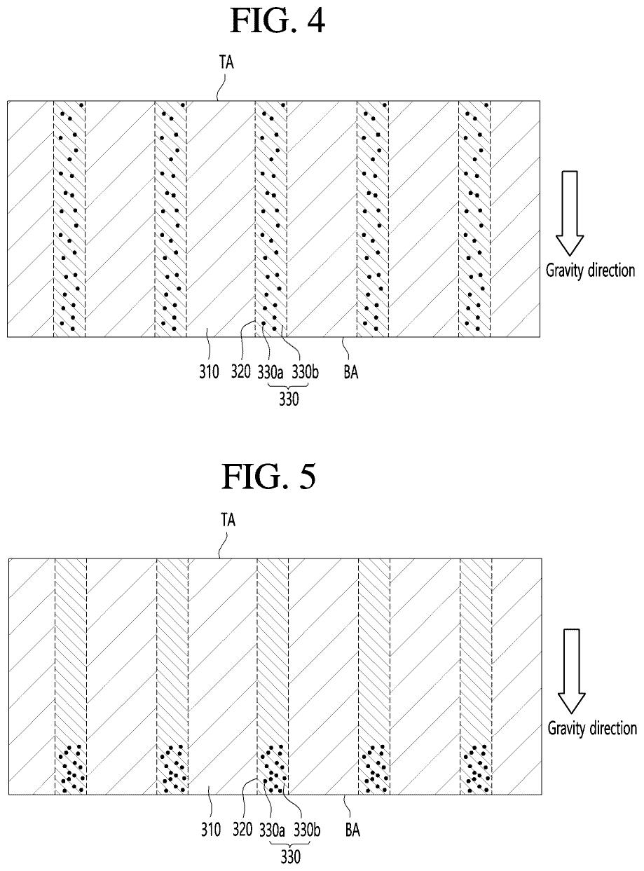

Referring to FIG. 4 and FIG. 5, the light conversion particles 330a can be settled into the lower area BA. The optical path control member 1000 is attached to the screen of the display device. Accordingly, the light conversion particles 330a can be settled in the direction of gravity.

Accordingly, when the optical path control member is used in the privacy mode for a long time, the light conversion particles 330a are settled from the upper area TA to the lower area BA. Therefore, in the privacy mode, the light shielding characteristic of the upper area TA of the optical path control member is reduced.

In order to solve the above problem, the optical path control member according to the embodiment includes light conversion particles 330a having a sedimentation velocity in a set range. The sedimentation velocity is defined as a distance that the light conversion particles 330a move from the upper area TA to the lower area BA in one day. That is, the sedimentation velocity is defined as a velocity of the light conversion particles moving in the length L direction of the receiving portion 320.

In detail, the light conversion particles 330a may have a sedimentation velocity of 0.7 mm/day or less. In detail, the light conversion particles 330a may have a sedimentation velocity of 0.001 mm/day to 0.7 mm/day. More specifically, the light conversion particles 330a may have a sedimentation velocity of 0.002 mm/day to 0.1 mm/day. More specifically, the light conversion particles 330a may have a sedimentation velocity of 0.003 mm/day to 0.03 mm/day.

The sedimentation velocity of the light conversion particles 330a may be controlled by a particle size of the light conversion particles 330a. The sedimentation velocity is proportional to the particle size of the light conversion particles 330a. That is, as the particle size of the light conversion particles 330a becomes smaller, the sedimentation velocity becomes smaller.

To this end, the light conversion particles 330a may have a particle size within a set range. Specifically, the light conversion particles 330a may have a particle size of 50 nm to 150 nm. Accordingly, the light conversion particles 330a may have a sedimentation velocity within a set range.

Alternatively, the sedimentation velocity of the light conversion particles 330a may be controlled by a specific gravity size of the light conversion particles 330a. The sedimentation velocity is proportional to the difference between the specific gravity of the light conversion particles 330a and the specific gravity of the dispersion liquid 330b. That is, as the difference between the specific gravity of the light conversion particles 330a and the specific gravity of the dispersion liquid 330b becomes smaller, the sedimentation velocity becomes smaller.

For this purpose, the light conversion particles 330a may have a specific gravity size within a set range. Specifically, the light conversion particles 330a may have a specific gravity of 1.3 to 1.8. Accordingly, the light conversion particles 330a may have a sedimentation velocity within a set range.

The optical path control member according to the embodiment includes light conversion particles having a sedimentation velocity within a set range. Accordingly, when the optical path control member is in a privacy mode or a power-off mode, the amount of the light conversion particles that are settled in the direction of gravity may be reduced. Accordingly, the optical path control member may be operated for a long time while having improved light-shielding characteristics.

Meanwhile, the sedimentation velocity of the light conversion particles is proportional to a movement speed of the light conversion particles. The sedimentation velocity of the light conversion particles 330a is defined as the movement speed in the longitudinal direction (L) of the receiving portion 320. In addition, the movement speed of the light conversion particles 330a is defined as the movement speed in the depth direction of the receiving portion 320.

That is, when the sedimentation velocity of the light conversion particles decreases, the movement speed of the light conversion particles decreases. Accordingly, when all of the light conversion particles have sedimentation velocities within a set range, the driving characteristics of the optical path control member may decrease.

Accordingly, the optical path control member according to the embodiment may include light conversion particles having different sedimentation velocities.

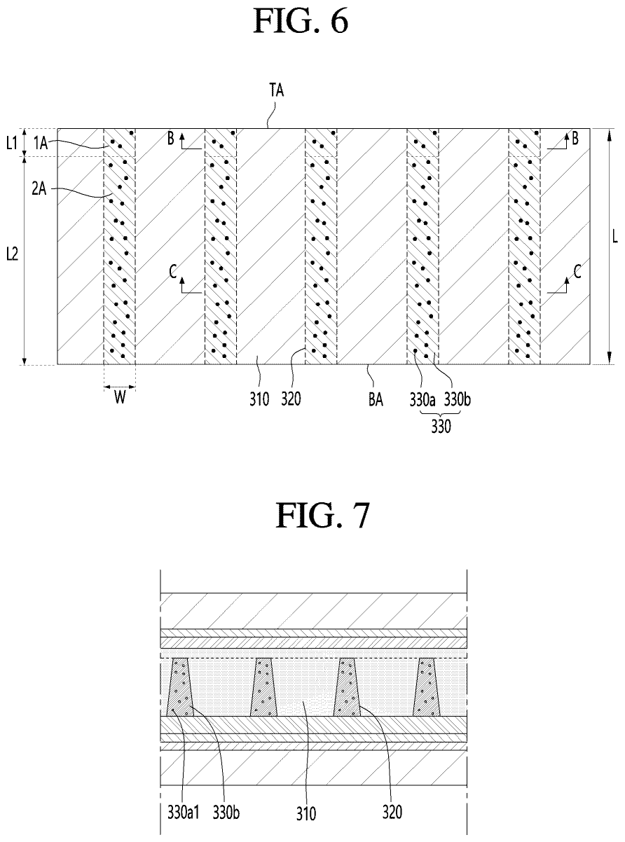

Referring to FIG. 6, the receiving portion 320 includes a plurality of regions. For example, the receiving portion 320 includes a first region 1A and a second region 2A. The first region 1A and the second region 2A are separated based on the length direction of the receiving portion 310.

The first region 1A is closer to the upper area TA than the second region 2A. The first region 1A and the second region 2A have different lengths. In detail, the first length L1 of the first region is smaller than the second length L2 of the second region.

Accordingly, the widths W of the first region 1A and the second region 2A are the same or similar, and further, the lengths of the first region 1A and the second region 2A are different.

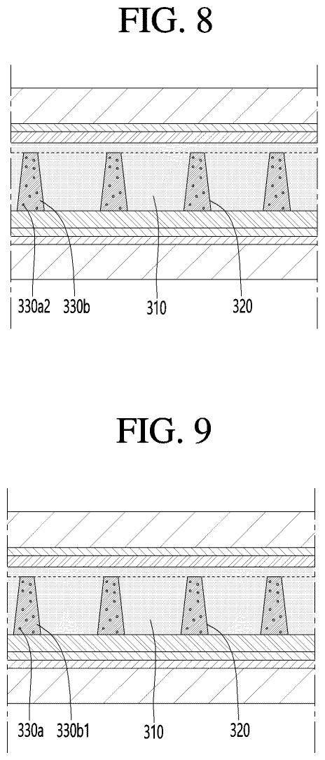

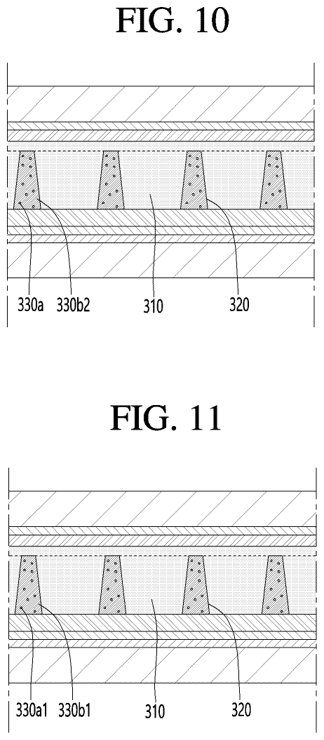

Referring to FIG. 7 and FIG. 8, the first light conversion particles 330a1 are arranged in the first region 1A. In the second region 2A, second light conversion particles 330a2 are arranged.

The first light conversion particles 330a1 and the second light conversion particles 330a2 have different particle sizes. In detail, the particle size of the first light conversion particles 330a1 is smaller than that of the second light conversion particles 330a2.

In addition, the first light conversion particles 330a1 and the second light conversion particles 330a2 have different specific gravities. In detail, the specific gravities of the first light conversion particles 330a1 are smaller than that of the second light conversion particles 330a2. In addition, the specific gravities of the first light conversion particles 330a1 and the second light conversion particles 330a2 are larger than that of the dispersion liquid 330b.

Accordingly, the first light conversion particles 330a1 and the second light conversion particles 330a2 have different sedimentation velocities. In detail, the sedimentation velocity of the first light conversion particles 330a1 is smaller than the sedimentation velocity of the second light conversion particles 330a2.

In detail, the particle size and/or specific gravity of the first light conversion particles 330a1 are smaller than the particle size and/or specific gravity of the second light conversion particles 330a2. Therefore, the sedimentation velocity of the first light conversion particles 330a1 becomes smaller than the sedimentation velocity of the second light conversion particles 330a2.

In addition, the first light conversion particles 330a1 and the second light conversion particles 330a2 have different moving speeds. In detail, the movement velocity of the first light conversion particles 330a1 is smaller than the movement velocity of the second light conversion particles 330a2.

In detail, the particle size and/or specific gravity of the second light conversion particles 330a2 are larger than the particle size and/or specific gravity of the first light conversion particles 330a1. Therefore, the movement velocity of the second light conversion particles 330a2 becomes larger than the movement velocity of the first light conversion particles 330a1.

Since the sedimentation velocity of the first light conversion particles 330a1 arranged in the first region 1A becomes smaller, the light shielding characteristic of the optical path control member can be prevented from decreasing in the privacy mode.

In addition, the second region 2A is larger than the first region 1A. The movement velocity of the second light conversion particles 330a1 arranged in the second region 2A is large. Therefore, the driving characteristics of the optical path control member can be improved. That is, the driving speed of the optical path control member can be improved.

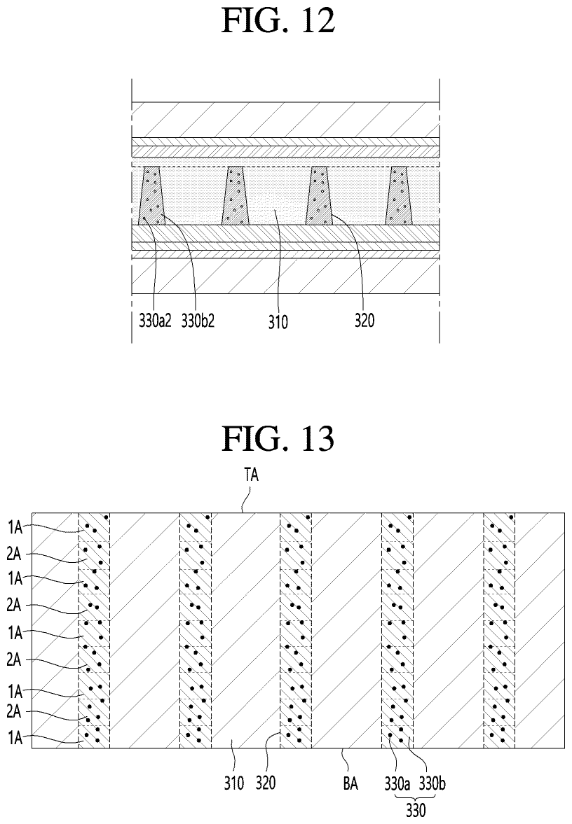

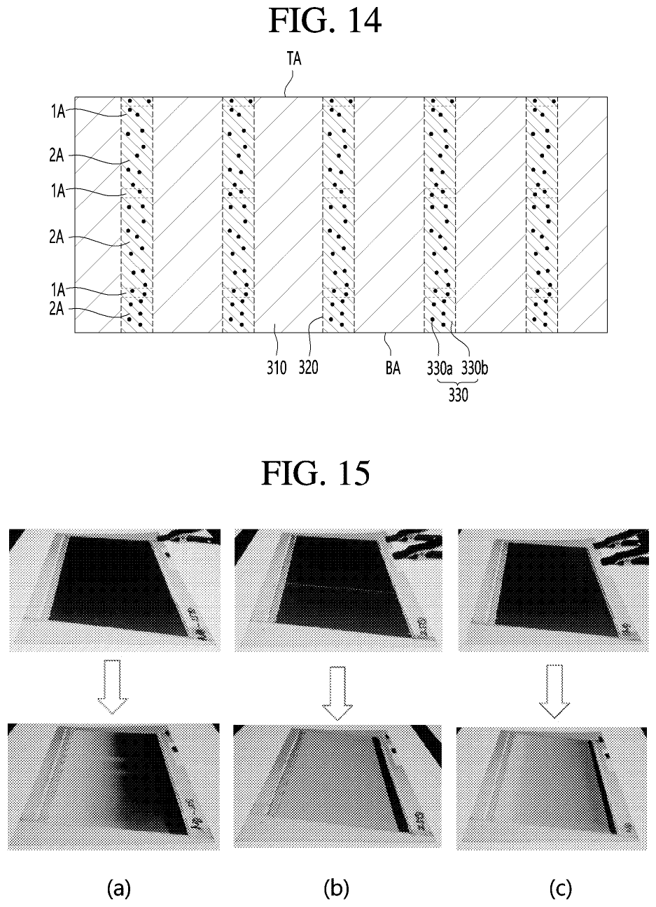

Referring to FIG. 9 and FIG. 10, the first dispersion liquid 330b1 is arranged in the first region 1A. The second dispersion liquid 330b2 is arranged in the second region 2A.

The first dispersion liquid 330b1 and the second dispersion liquid 330b2 have different specific gravities. In detail, the specific gravity of the first dispersion liquid 330b1 is greater than the specific gravity of the second dispersion liquid 330b2. In addition, the specific gravities of the first dispersion liquid 330b1 and the second dispersion liquid 330b2 are less than the specific gravities of the light conversion particles 330a.

Accordingly, the sedimentation velocity of the light conversion particles 330a arranged in the first region 1A is less than the sedimentation velocity of the light conversion particles 330a arranged in the second region 2A.

In detail, the specific gravity of the first dispersion liquid 330b1 is greater than the specific gravity of the second dispersion liquid 330b2. Accordingly, the difference in the specific gravity between the light conversion particles 330a and the first dispersion liquid 330b1 becomes smaller than the difference in the specific gravity between the light conversion particles 330a and the second dispersion liquid 330b2. Therefore, the sedimentation velocity of the light conversion particles 330a in the first region 1A becomes smaller than the sedimentation velocity of the light conversion particles 330a in the second region 2A.

In addition, the movement velocity of the light conversion particles 330a arranged in the second region 2A becomes greater than the movement velocity of the light conversion particles 330a arranged in the first region 1A.

In detail, the specific gravity of the first dispersion liquid 330b1 is greater than the specific gravity of the second dispersion liquid 330b2. Accordingly, the difference in specific gravity between the light conversion particles 330a and the second dispersion liquid 330b2 becomes greater than the difference in specific gravity between the light conversion particles 330a and the first dispersion liquid 330b1. Therefore, the movement velocity of the light conversion particles 330a arranged in the second region 2A becomes greater than the movement velocity of the light conversion particles 330a arranged in the first region 1A.

Therefore, since the sedimentation velocity of the light conversion particles 330a arranged in the first region 1A becomes smaller, the light shielding characteristic of the optical path control member can be prevented from decreasing in the privacy mode.

In addition, since the movement velocity of the light conversion particles 330a arranged in the second region 2A becomes larger, the driving characteristic of the optical path control member can be improved. That is, the driving speed of the optical path control member can be improved.

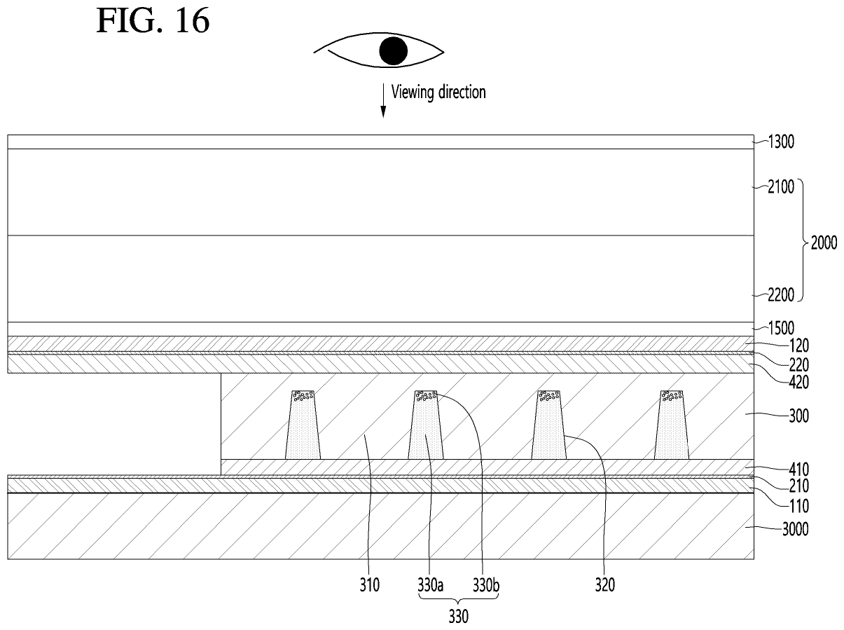

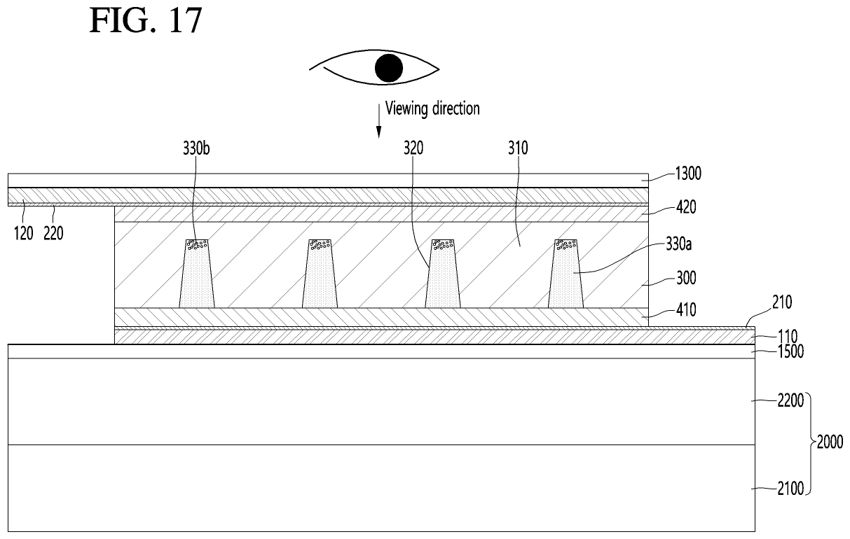

Referring to FIG. 11 and FIG. 12, the first light conversion particles 330a1 and the first dispersion liquid 330b1 are arranged in the first region 1A. In addition, the second light conversion particles 330a2 and the second dispersion liquid 330b2 are arranged in the second region 2A.

The first light conversion particles 330a1 and the second light conversion particles 330a2 have different particle sizes. In detail, the particle size of the first light conversion particles 330a1 is smaller than the particle size of the second light conversion particles 330a2.

In addition, the first light conversion particles 330a1 and the second light conversion particles 330a2 have different specific gravities. In detail, the specific gravity of the first light conversion particles 330a1 is smaller than that of the second light conversion particles 330a2. In addition, the specific gravity of the first light conversion particles 330a1 and the second light conversion particles 330a2 is larger than that of the first dispersion liquid 330b1 and the second dispersion liquid 330b2.

In addition, the first dispersion liquid 330b1 and the second dispersion liquid 330b2 have different specific gravity. In detail, the specific gravity of the first dispersion liquid 330b1 is larger than that of the second dispersion liquid 330b2.

Accordingly, the first light conversion particles 330a1 and the second light conversion particles 330a2 have different sedimentation velocities. In detail, the sedimentation velocity of the first light conversion particles 330a1 is smaller than the sedimentation velocity of the second light conversion particles 330a2.

In detail, the particle size and/or specific gravity of the first light conversion particles 330a1 are smaller than the particle size and/or specific gravity of the second light conversion particles 330a2. Therefore, the sedimentation velocity of the first light conversion particles 330a1 becomes smaller than the sedimentation velocity of the second light conversion particles 330a2.

In addition, the specific gravity of the first dispersion liquid 330b1 is larger than the specific gravity of the second dispersion liquid 330b2. Accordingly, the difference in specific gravity between the first light conversion particles 330a1 and the first dispersion liquid 330b1 becomes smaller than the difference in specific gravity between the second light conversion particles 330a2 and the second dispersion liquid 330b2. Therefore, the sedimentation velocity of the first light conversion particles 330a1 becomes smaller than the sedimentation velocity of the second light conversion particles 330a2.

In addition, the first light conversion particles 330a1 and the second light conversion particles 330a2 have different moving speeds. In detail, the moving speed of the first light conversion particles 330a1 is smaller than the moving speed of the second light conversion particles 330a2.

In detail, the particle size and/or specific gravity of the second light conversion particles 330a2 are larger than the particle size and/or specific gravity of the first light conversion particles 330a1. Therefore, the moving speed of the second light conversion particles 330a2 becomes larger than the moving speed of the first light conversion particles 330a1.

In addition, the specific gravity of the first dispersion liquid 330b1 is greater than that of the second dispersion liquid 330b2. Accordingly, the difference in the specific gravity between the second light conversion particles 330a2 and the second dispersion liquid 330b2 becomes greater than the difference in the specific gravity between the first light conversion particles 330a1 and the first dispersion liquid 330b1. Accordingly, the movement velocity of the light conversion particles 330a arranged in the second region 2A becomes greater than the movement velocity of the light conversion particles 330a arranged in the first region 1A.

Therefore, the sedimentation velocity of the first light conversion particles 330a1 arranged in the first region 1A is small. Accordingly, the light shielding characteristic of the optical path control member can be prevented from decreasing in the privacy mode.

In addition, the second region 2A is larger than the first region 1A. The movement speed of the second light conversion particles 330a1 arranged in the second region 2A is large. Therefore, the driving characteristics of the optical path control member can be improved. That is, the driving speed of the optical path control member can be improved.

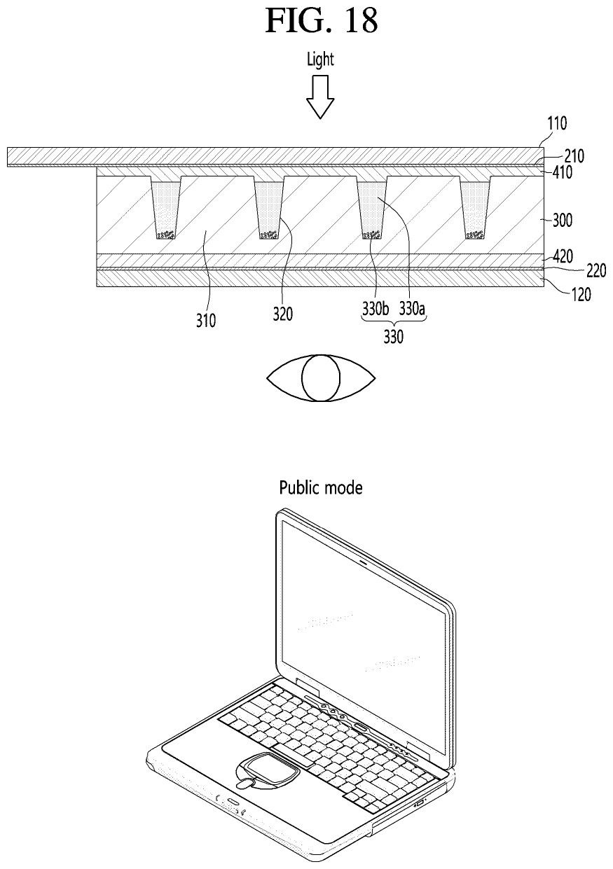

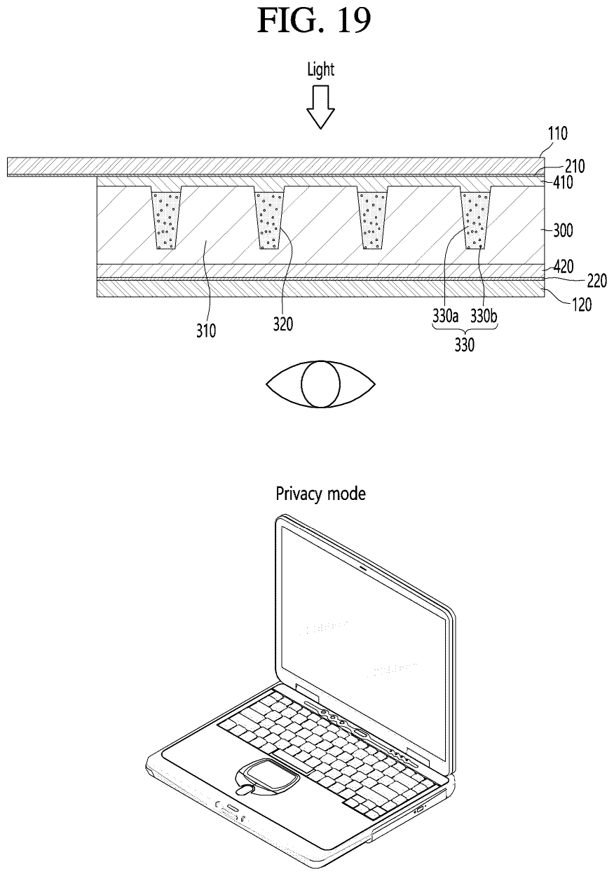

Referring to FIG. 13 and FIG. 14, the receiving portion 320 includes a plurality of first regions 1A and a plurality of second regions 2A.

The first region 1A and the second region 2A are arranged alternately. In addition, the first light conversion particles, the second light conversion particles, the first dispersion liquid and the second dispersion liquid described in FIG. 7 to FIG. 12 may be arranged in the first region 1A and the second region 2A.

The first region 1A and the second region 2A may be formed with the same or different lengths. For example, as in FIG. 13, the first region 1A and the second region 2A are formed with the same or similar lengths. Or, as in FIG. 14, the first region 1A and the second region 2A are formed with different lengths. For example, the sum of the lengths of the second region 2A is greater than the sum of the lengths of the first region 1A.

The first region and the second region are arranged alternately. Therefore, the sedimentation of the light conversion particles can be reduced in the entire region of the optical path control member. That is, the velocity of the light conversion particles sedimenting in the second region can be reduced by the first region. In detail, the sedimentation velocity is small in the first region. Therefore, the light conversion particles sedimenting in the second region are blocked by the light conversion particles of the first region. Therefore, the sedimentation velocity of the light conversion particles can be reduced. That is, the first region can act as a buffer layer.

In addition, the sum of the lengths of the second region 2A is greater than the sum of the lengths of the first region 1A. Accordingly, the sedimentation velocity of the light conversion particles can be reduced. In addition, the moving speed of the light conversion particles can be increased.

Therefore, the optical path control member has improved light blocking characteristics in the privacy mode. In addition, the driving speed of the optical path control member can be improved in the privacy and public modes.

Hereinafter, the present invention will be described in more detail through measurements of the degree of sedimentation of light conversion particles according to examples of embodiment and comparative examples. These examples of embodiment are merely presented as examples in order to describe the present invention in more detail. Therefore, the present invention is not limited to these examples.

### Example 1

A first electrode is formed on one side of a first substrate. In addition, a second electrode is formed on one side of a second substrate. The first substrate and the second substrate include polyethylene terephthalate (PET). The first electrode and the second electrode include indium tin oxide (ITO).

Next, a urethane or epoxy-based buffer layer is formed on the first electrode. Next, a urethane or epoxy-based resin layer is formed on the buffer layer. Next, a pattern is formed on the resin layer by an imprinting process. As a result, a receiving portion is formed.

Then, the resin layer and the second substrate are bonded by an optically transparent adhesive (OCA).

Then, a plurality of cutting areas are formed in the first substrate or the second substrate. Then, a light conversion material is filled inside the receiving portion. The light conversion material includes carbon particles and dispersion liquid. Then, a sealing material is filled in the cutting area. Then, UV is irradiated to harden the sealing material.

The carbon particles include first particles and second particles. The sedimentation velocity of the first particle is 0.016 mm/day. The sedimentation velocity of the second particle is 0.75 mm/day. The first particle is arranged in an area smaller than the bezel area in the upper area. The second particle is arranged in the remaining area.

Then, the sedimentation of the carbon particles is measured.

### Example 2

An optical path control member is manufactured in the same manner as in Example 1, except that the carbon particles include only the first particles. Then, the sedimentation of the carbon particles is measured.

### Comparative Example

An optical path control member is manufactured in the same manner as in Example 1, except that the carbon particles include only the second particles. Then, the sedimentation of the carbon particles is measured.

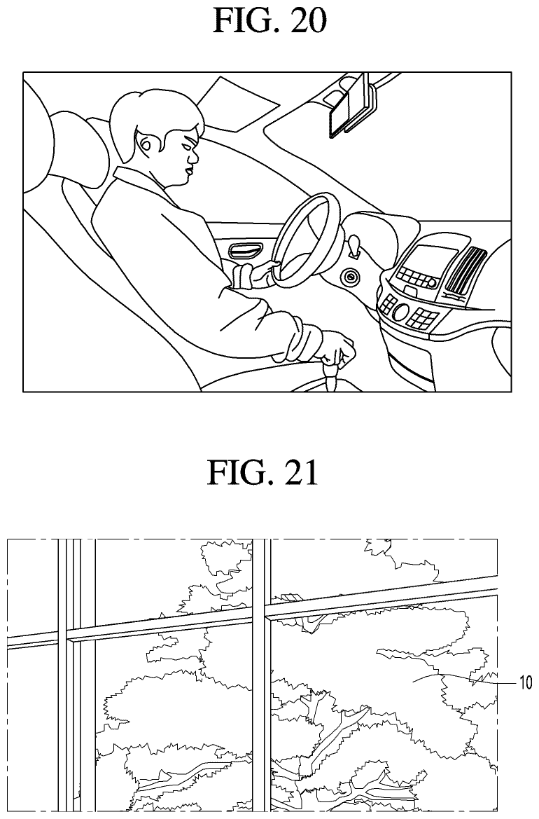

FIG. 15 (a) is an optical path control member of Example 1. FIG. 15 (b) is an optical path control member of Example 2. FIG. 15 (c) is an optical path control member of a comparative example.

Referring to FIG. 15, Example 1 comprises carbon particles having first particles having a low sedimentation velocity and second particles having a high sedimentation velocity. Therefore, it can be seen that the optical path control member maintains a light-shielding characteristic in the lower region. In addition, Example 2 comprises carbon particles only having the first particle having first particles having a low sedimentation velocity. Therefore, the light-shielding ratio of the optical path control member decreases. However, it can be seen that the light-shielding characteristic of the optical path control member is maintained.

On the other hand, the comparative example comprises carbon particles only having the second particle having a high sedimentation velocity. Therefore, the light-shielding characteristic is significantly reduced in the upper region. Accordingly, it can be seen that light is transmitted in the upper region of the optical path control member.

That is, the optical path control member according to the embodiment reduces the sedimentation velocity of the light conversion particles. Or, light conversion particles having different sedimentation velocities are arranged in each region. Accordingly, the light-shielding characteristic of the optical path control member can be improved.

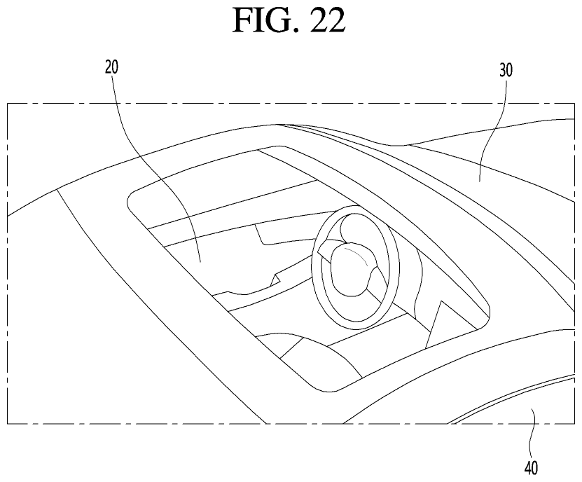

Hereinafter, a display terminal and a display device to which the optical path control member according to the embodiment is applied will be described with reference to FIGS. 16 to 22.

Referring to FIG. 16 and FIG. 17, the optical path control member 1000 according to the embodiment may be arranged on or below the display panel 2000.

The display panel 2000 and the optical path control member 1000 may be adhered to each other. For example, the display panel 2000 and the optical path control member 1000 may be adhered by an adhesive member 1500. The adhesive member 1500 may be transparent.

The display panel 2000 may include a first base substrate 2100 and a second base substrate 2200. The first base substrate 2100 may include a thin film transistor (TFT) and a pixel electrode. The second base substrate 2200 may include color filter layers.

Alternatively, the display panel 2000 may include a liquid crystal display panel or an organic light-emitting display panel.

As shown in FIG. 16, if the display panel 2000 is a liquid crystal display panel, the optical path control member may be arranged at the bottom of the liquid crystal display panel. The optical path control member may be arranged between the backlight unit 3000 and the display panel 2000.

Alternatively, as shown in FIG. 17, if the display panel 2000 is an organic light-emitting display panel, the optical path control member may be arranged at the top of the organic light-emitting display panel.

Although not shown in the drawing, a polarizing plate may be further arranged between the optical path control member 1000 and the display panel 2000. The polarizing plate may be a linear polarizing plate or an external light reflection prevention polarizing plate. For example, if the display panel 2000 is a liquid crystal display panel, the polarizing plate may be the linear polarizing plate. In addition, if the display panel 2000 is an organic light emitting display panel, the polarizing plate may be the external light reflection prevention polarizing plate.

In addition, a functional layer 1300 may be further arranged on the optical path control member 1000. The functional layer 1300 may include an anti-reflection layer. The functional layer 1300 may be adhered to one side of the second substrate 120 of the optical path control member.

In addition, a touch panel may be further arranged between the display panel and the optical path control member.

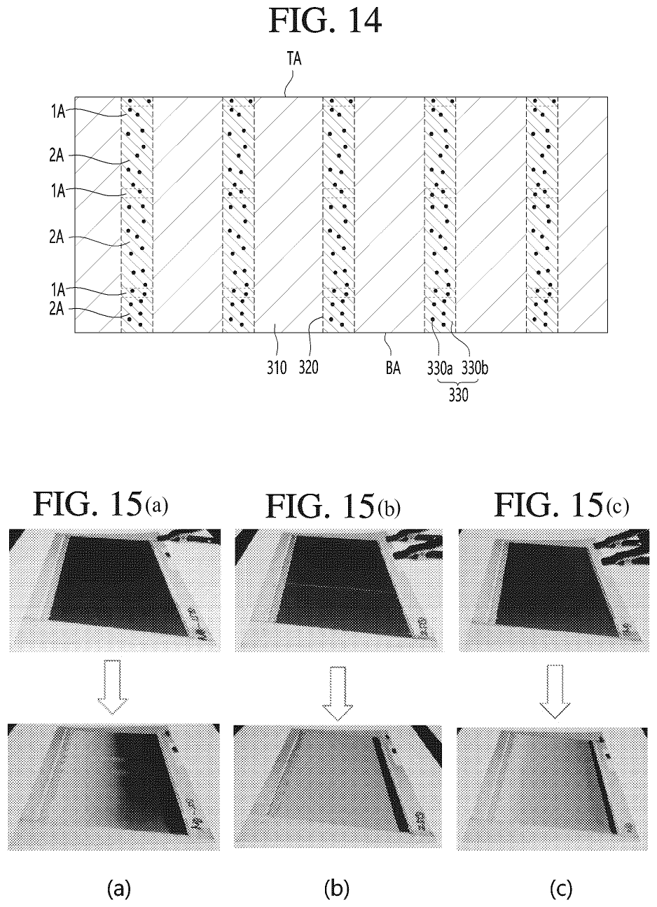

Referring to FIGS. 18 to 22, the optical path control member may be applied to various display devices.

Referring to FIGS. 18 and 19, the optical path control member may be applied to a display device.

When power is applied to the optical path control member as in FIG. 18, the receiving portion is driven as a light transmitting portion. Accordingly, the display device is driven in a public mode. Or, when power is not applied to the optical path control member as in FIG. 19, the receiving portion is driven as a light blocking portion. Accordingly, the display device is driven in a privacy mode.

Accordingly, the user can drive the display device in a public mode or a privacy mode.

The light emitted from the backlight unit or the self-luminous element can move from the first substrate toward the second substrate. Or, the light can move from the second substrate toward the first substrate.

Referring to FIGS. 20 to 22, the optical path control member can be applied to the interior and exterior of a vehicle and windows of a building.

As in FIG. 20, the display device including the optical path control member can display a video for confirming vehicle information or a vehicle movement path. The display device can be placed between the driver's seat and the passenger's seat of the vehicle.

In addition, the optical path control member can be applied to an instrument panel of the vehicle.

In addition, as shown in FIG. 21, the optical path control member can be applied to the window 10 of the building. Accordingly, the amount of light passing through the window 10 can be controlled.

In addition, as shown in FIG. 22, the optical path control member may be applied to a sunroof 20, windshield 30, or left and right windows 40 of the vehicle.

The features, structures, effects, etc. described in the above-described embodiments are included in at least one embodiment of the present invention, and are not necessarily limited to one embodiment. Furthermore, the features, structures, effects, etc. exemplified in each embodiment may be combined or modified and implemented in other embodiments by a person having ordinary knowledge in the field to which the embodiments belong. Therefore, the contents related to such combinations and modifications should be interpreted as being included in the scope of the present invention.

In addition, although the embodiments have been described above, they are merely examples and do not limit the present invention, and a person having ordinary knowledge in the field to which the present invention belongs will understand that various modifications and applications not exemplified above are possible without departing from the essential characteristics of the present embodiments. For example, each component specifically shown in the embodiments may be modified and implemented. And the differences related to these modifications and applications should be construed as being included within the scope of the present invention defined in the appended claims.

1. An optical path control member, comprising:
a first substrate;
a first electrode disposed on the first substrate;
a second substrate disposed on the first substrate;
a second electrode disposed under the second substrate; and
an optical converter disposed between the first electrode and the second electrode,
wherein the optical converter includes a receiving portion and a partition wall alternately disposed,
a light conversion material including a dispersion liquid and light conversion particles dispersed in the dispersion liquid is disposed inside the receiving portion,
a sedimentation velocity of the light conversion particles is 0.001 mm/day to 0.7 mm/day, and
the sedimentation velocity of the light conversion particles is a velocity of the light conversion particles moving in a longitudinal direction of the receiving portion.

2. The optical path control member of claim 1, wherein a particle size of the light conversion particles is 50 nm to 150 nm.

3. The optical path control member of claim 1, wherein a specific gravity of the light conversion particles is 1.3 to 1.8.

4. An optical path control member, comprising:
a first substrate;
a first electrode disposed on the first substrate;
a second substrate disposed on the first substrate;
a second electrode disposed under the second substrate; and
an optical converter disposed between the first electrode and the second electrode,
wherein the optical converter includes a receiving portion and a partition wall alternately disposed,
a light conversion material including a dispersion liquid and light conversion particles dispersed in the dispersion liquid is disposed inside the receiving portion,
the receiving portion includes a first region and a second region separated in a length direction of the receiving portion,
a length of the first region is smaller than a length of the second region, and
a sedimentation velocity of the light conversion particles disposed in the first region is smaller than a sedimentation velocity of the light conversion particles disposed in the second region.

5. The optical path control member of claim 4, wherein a movement speed of the light conversion particles arranged in the second region is greater than a movement speed of the light conversion particles arranged in the first region,
a sedimentation velocity of the light conversion particles is a speed of the light conversion particles moving in the length direction of the receiving portion, and
the movement speed of the light conversion particles is a speed of the light conversion particles moving in a depth direction of the receiving portion.

6. The optical path control member of claim 4, wherein first light conversion particles are disposed in the first region,
second light conversion particles are disposed in the second region, and
a particle size of the first light conversion particles is smaller than a particle size of the second light conversion particles.

7. The optical path control member of claim 4, wherein first light conversion particles are disposed in the first region,
second light conversion particles are disposed in the second region, and
a specific gravity of the first light conversion particles is smaller than a specific gravity of the second light conversion particles.

8. The optical path control member of claim 4, wherein a first dispersion liquid is disposed in the first region,
a second dispersion liquid is disposed in the second region, and
a specific gravity of the first dispersion liquid is greater than a specific gravity of the second dispersion liquid.

9. The optical path control member of claim 4, wherein first light conversion particles and a first dispersion liquid are disposed in the first region,
second light conversion particles and a second dispersion liquid are disposed in the second region, and
a particle size of the first light conversion particles is smaller than a particle size of the second light conversion particles.

10. The optical path control member of claim 4, wherein first light conversion particles and a first dispersion liquid are disposed in the first region,
second light conversion particles and a second dispersion liquid are disposed in the second region,
a specific gravity of the first light conversion particles is smaller than a specific gravity of the second light conversion particles, and
a specific gravity of the first dispersion liquid is greater than a specific gravity of the second dispersion liquid.

11-15. (canceled)

16. The optical path control member of claim 5, wherein first light conversion particles are disposed in the first region,
second light conversion particles are disposed in the second region, and
a particle size of the first light conversion particles is smaller than a particle size of the second light conversion particles.

17. The optical path control member of claim 5, wherein first light conversion particles are disposed in the first region,
second light conversion particles are disposed in the second region, and
a specific gravity of the first light conversion particles is smaller than a specific gravity of the second light conversion particles.

18. The optical path control member of claim 5, wherein a first dispersion liquid is disposed in the first region,
a second dispersion liquid is disposed in the second region, and
a specific gravity of the first dispersion liquid is greater than a specific gravity of the second dispersion liquid.

19. The optical path control member of claim 5, wherein first light conversion particles and a first dispersion liquid are disposed in the first region,
second light conversion particles and a second dispersion liquid are disposed in the second region, and
a particle size of the first light conversion particles is smaller than a particle size of the second light conversion particles.

20. The optical path control member of claim 5, wherein first light conversion particles and a first dispersion liquid are disposed in the first region,
second light conversion particles and a second dispersion liquid are disposed in the second region,
a specific gravity of the first light conversion particles is smaller than a specific gravity of the second light conversion particles, and
a specific gravity of the first dispersion liquid is greater than a specific gravity of the second dispersion liquid.
